(19) United States
(12) Patent Application Publication
(10) Pub. No.: US 2019/0285701 A1
(43) Pub. Date: Sep. 19, 2019

(54) Determining Capacitance of an Energy Store of an Uninterruptible Direct Current Supply Unit

(71) Applicant: Siemens Aktiengesellschaft, Muenchen (DE)

(72) Inventor: Christian Augesky, Wien (AT)

(21) Appl. No.: 16/300,688

(22) PCT Filed: May 5, 2017
(86) PCT No.: PCT/EP2017/060742

§ 371 Date: Nov. 12, 2018

(30) Foreign Application Priority Data
May 12, 2016 (DE) 10 2016 208 194.2

(51) Int. Cl. G01R 31/385; H02J 7/00; H02J 9/06; H01M 10/48

(52) U.S. Cl. CPC G01R 31/386; H01M 10/482; H02J 9/062; H02J 7/0026

(57) ABSTRACT

A method for determining the capacitance of an energy store of a direct current supply unit for an uninterruptible supply of direct current to a load, wherein the direct current supply unit includes at least one input for an input voltage, one output for a DC output voltage, and two identical energy stores which provide a standby DC output voltage during buffer mode, where a charged first energy store is fully discharged at predefined intervals via a load applied to the output, the first energy store is charged from the fully charged second energy store, the second energy store is fully charged again via the input, and where the capacitance taken from the second energy store is measured in the second step and/or the capacitance in the charged second energy store is measured in the third step to determine the actual capacitance without jeopardizing the buffer mode.

### CROSS-REFERENCE TO RELATED APPLICATIONS

This is a U.S. national stage of application No. PCT/EP2017/060742 filed May 5, 2017. Priority is claimed on German Application No. 102016208194 filed May 12, 2016, the content of which is incorporated herein by reference in its entirety.

### BACKGROUND OF THE INVENTION

### 1. Field of the Invention

The invention relates to a non-transitory computer program product, a DC power supply unit and to a method for determining the capacity of an energy store of a DC power supply unit for an uninterruptible supply of direct current to a load, where the DC power supply unit comprises at least an input for an input voltage, an output for a DC output voltage, from which output a load connected to said output can draw a load current, and two similar energy stores, which are charged via the input by a charging current and which, during backup mode, provide a replacement DC output voltage.

### 2. Description of the Related Art

The input voltage may be both an AC voltage and a DC voltage. In normal mode, the DC power supply unit provides the DC output voltage by converting a DC input voltage or by rectifying an AC input voltage. If there is no input voltage available, or the input voltage is not high enough, then the DC power supply unit switches into backup mode, during which the DC output voltage is provided by the energy store, such as a rechargeable battery or a primary battery.

An uninterruptible power supply unit supplies a load connected to the output even during a drop in the supply voltage, which is referred to here as the input voltage. In addition to the load, at least one energy store, such as a rechargeable battery, of the uninterruptible power supply unit is also connected to the input voltage. These energy stores are charged during normal mode, and used as an energy supplier during backup mode after a drop in the supply voltage.

Assessing the performance and the service life or availability that is still expected of rechargeable batteries fundamentally depends on determining the available battery capacity and voltage level reliably by discharging under defined measurement conditions. If such a measurement is performed during operation of the power supply unit, then the power supply unit is not available for backup mode for the duration of the measurement, and therefore the power supply will fail in the event of faults in the utility supply.

For this reason, measuring the capacity by discharging down to the discharge cutoff voltage is often dispensed with in favor of trying to use a brief partial discharge to determine the capacity of the rechargeable battery from the variation in the battery voltage and stored reference values. Although the power supply unit continues to be available in principle in this case, the quality of the information on the capacity of the rechargeable battery is lower.

If a backup mode actually arises in which discharge is down to the discharge cutoff voltage, it is possible in this case to derive information about the capacity and service life that is still expected of the rechargeable battery by evaluating the values measured during the backup mode. An actual backup mode arises rarely, however, and then even a full discharge down to the discharge cutoff voltage does not necessarily occur. Consequently, this form of evaluation is not suitable for continuous monitoring of the rechargeable battery and prompt warning of its imminent failure.

It is also possible to calculate the capacity and service life of a rechargeable battery from a detailed model of the rechargeable battery and taking into account all the environmental variables, the load situations and accompanying measurements of the service life of the actual rechargeable battery, although this calculation also suffers from a high degree of inaccuracy.

Ultimately, only a full discharge of the rechargeable battery under defined conditions gives a good basis for determining the capacity and service life of a rechargeable battery.

### SUMMARY OF THE INVENTION

In view of the foregoing, it is therefore an object of the present invention to provide a method that can be used to determine the actual instantaneous capacity of an energy store of a DC power supply unit while a backup mode is still possible simultaneously.

This and other objects and advantages are achieved in accordance with the invention by a method for determining the capacity of an energy store of a DC power supply unit for the uninterruptible supply of direct current to a load, where the DC power supply unit comprises at least an input for an input voltage, an output for a DC output voltage, from which output a load connected to the output can draw a load current, and two similar energy stores, which are charged via the input by a charging current, and in backup mode provide a replacement DC output voltage.

The method provides that the capacity of each of the two energy stores is dimensioned for one energy store alone to be able to provide the backup mode, where in a first step, a charged first energy store is fully discharged at specified time intervals via a load applied to the output, in a second step, the first energy store is charged from the fully charged second energy store, and in a third step, the second energy store is recharged fully via the input, where during the second step, the capacity taken from the second energy store is measured, and/or during the third step, the capacity charged into the second energy store is measured.

The method in accordance with the invention requires two similar energy stores, in particular rechargeable batteries, for the uninterruptible DC power supply unit, so for instance two identical products. They should at least have the same capacity, however. In this regard, each of the two energy stores can be a “first energy store” or a “second energy store”.

In normal mode, the two energy stores are 100% charged and backup-ready. That is, double the required capacity is available for backup mode. Throughout the method in accordance with the invention, at least the capacity of one energy store is always available in total. Thus, should a utility supply dropout occur, then the capacity of one energy store is always available for the backup mode. In the first step, the fully charged second energy store is available. In the second step, the partially charged first energy store and partially charged second energy store are available. In the third step, the fully charged first energy store is available.

The fact that during the method in accordance with the invention, at least one of the energy stores is always fully discharged under controlled conditions and no load, and then recharged fully under controlled conditions means that the measurement data from the discharging and/or charging process can be used to calculate at least the actual capacity. “Controlled conditions” is understood to mean a constant, predefined current for which it is possible to determine reproducible, comparable values for the stored capacity.

The capacity determined and taken under controlled conditions in the second step constitutes the fundamental indicator of the performance of the rechargeable battery and the still expected lifespan (usually the end of service life of the rechargeable battery is defined as the fall to 80% of the initial capacity).

In addition, the charging efficiency, which represents an additional indicator of the performance of the rechargeable battery, can be obtained by forming the quotient of discharged capacity to charged capacity.

It would also be conceivable that in the first step, during the discharge of the first energy store via the load, the capacity of the first energy store is determined based on measurements taken during the discharge, even if this is not so accurate as in the second or third step because the discharge current depends on the load conditions currently prevailing in the power supply system.

In order to have constant conditions during the second step, the first energy store is charged from the fully charged second energy store under constant current.

In order to have controlled conditions during the third step, the second energy store is usually recharged fully by constant current via the input.

In the second and third steps, the replacement DC output voltage, also referred to as the voltage level, of the second energy store can also be measured in addition to the capacity. The voltage level is measured at least in the fully charged state, although it can also be measured during the discharging and charging process under different states of charge.

If a device is provided for measuring the absolute service life of the energy store, this has the advantage that the service life up to this point is thereby known, and can be used to determine the expected service life of an energy store.

The service life of the energy store can be determined approximately from measured capacity, measured replacement DC output voltage (i.e., voltage level) and measured absolute service life at the time of measuring the capacity, and based on manufacturer data about the energy store. This process can also take into account additional operating conditions, such as the ambient temperature and the previous discharge depth(s) and discharge frequency/frequencies of occurrence.

In order to accurately know the capacity of both energy stores, the method in accordance with the invention is performed at specified time intervals alternately, in one case starting with the first energy store, and in another case starting with the second energy store. So, for instance, in the first month, the first rechargeable battery is discharged via the load in the first step, for example, and the capacity of the second rechargeable battery is determined in the second and/or third step. Then, in the subsequent month, the second rechargeable battery is discharged via the load in the first step, the second rechargeable battery is charged from the first rechargeable battery in the second step, and the first rechargeable battery is recharged via the input in the third step, whereby the capacity of the first rechargeable battery is determined. Then in the third month, the capacity of the second rechargeable battery is again determined, and so on.

This does not exclude, however, that both the capacity of the first energy store and the capacity of the second energy store are determined directly one after the other, i.e., the method in accordance with the invention is performed twice in succession using alternate energy stores.

The specified time interval at which the method in accordance with the invention is repeated at least once will typically be selectable and in particular will equal one month, for instance. The method in accordance with the invention should not be performed too frequently to avoid being the sole means of excessively reducing the service life of the rechargeable batteries. The time interval between two methods in accordance with the invention also must not be too large, however, because of course a rechargeable battery might have reached the end of its useful life in the intervening time. The time interval depends on the battery technology and the associated maximum possible discharge cycles. One month is a typical value that more or less meets these requirements for both lead-acid and lithium batteries.

The method in accordance with the invention is usually executed under computer control by a processor assigned to the DC power supply unit. This processor may form a physical part of the DC power supply unit, although it may also be separate from the DC power supply unit and connected thereto via a data connection. The processor may also execute other open-loop and closed-loop control functions for the DC power supply unit, or else an existing processor may perform the additional functions in accordance with the invention.

Thus, because the method in accordance with the invention is executed normally by a processor, the invention also relates to a non-transitory computer program product, which comprises a program and can be loaded directly into a memory of a processor of the DC power supply unit, and which has program means in order to perform all the steps of the method in accordance with the invention when the program is executed by the processor. The computer program product may be a data storage medium, for example, on which a corresponding computer program is stored, or it may be a signal or data stream, which can be loaded into the processor via a data connection.

It is also an object of the invention to provide a DC power supply unit for the uninterruptible supply of direct current to a load for the purpose of performing the method in accordance with the invention, and comprises at least an input for an input voltage, an output for a DC output voltage, from which output a load connected to said output can draw a load current, and two similar energy stores, which can be charged via the input by a charging current, and in backup mode can provide a replacement DC output voltage.

This DC power supply unit is characterized in that the capacity of each of the two energy stores is dimensioned for one energy store alone to be able to provide the backup mode, where the first energy store and the second energy store are provided with a switchable connection, such as by relays, via which the first energy store can be charged from the second energy store, and the second energy store can be charged from the first energy store, and where each energy store is provided with a device for measuring the capacity.

The switchable connection may comprise, for example, one or more relays. The device for measuring the capacity can comprise, for example, a current measuring device and a time measuring device. By measuring the current strength over time during charging and/or discharging, the amount of current in Ah (ampere hours) or, for smaller rechargeable batteries, in mAh (milliampere hours) that can be drawn from a fully charged energy store under specified conditions can be calculated as the capacity.

The DC power supply unit can also have a closed-loop control unit which can be used to regulate the charging current of the energy stores to a constant value, for instance as part of the charging circuit.

The DC power supply unit in accordance with the invention is constantly ready for operation, even during the method in accordance with the invention.

The measurement of the currently available capacity of the rechargeable batteries is completely independent of the load conditions, a situation that would not exist when discharging into the load.

The additional complexity of the DC power supply unit in accordance with the invention is confined to the facility for switching the charging circuit between the two rechargeable batteries, such as via relays or semiconductor switches, an addition to the connection device, and the facility for making electrical contact for a second rechargeable battery.

With limitations on the reliability, it is also possible to use just one rechargeable battery to measure the capacity of this rechargeable battery by discharging this battery into the load, and then recharging this battery, and determining the capacity from measured values during the charging and/or discharging.

With high backup currents or powers, there are often a plurality of similar rechargeable batteries already connected in parallel in existing uninterruptible DC power supply units to prevent damage to the rechargeable batteries under a high load. Here, it would only be necessary to modify the contact-making of the rechargeable batteries to the power supply in the sense that in the future they are connected individually to this base unit and can be checked using the method in accordance with the invention.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In order to explain the invention further, reference is made in the following part of the description to the figures, which suggest further advantageous embodiments, details and developments of the invention. The figures are intended by way of example, and although they are intended to present the nature of the invention, in no way restrict or even conclusively reflect this, in which:

FIG. 1 shows a DC power supply unit during the discharge of a first rechargeable battery via a load in accordance with the invention;

FIG. 2 shows the DC power supply unit during the discharge of a second rechargeable battery into the first rechargeable battery in accordance with the invention;

FIG. 3 shows the DC power supply unit during the charging of a second rechargeable battery; and

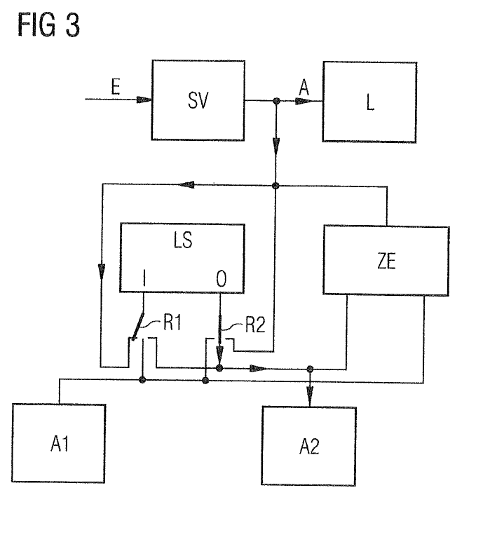

FIG. 4 is a flowchart of the method in accordance with the invention.

### DETAILED DESCRIPTION OF THE EXEMPLARY EMBODIMENTS

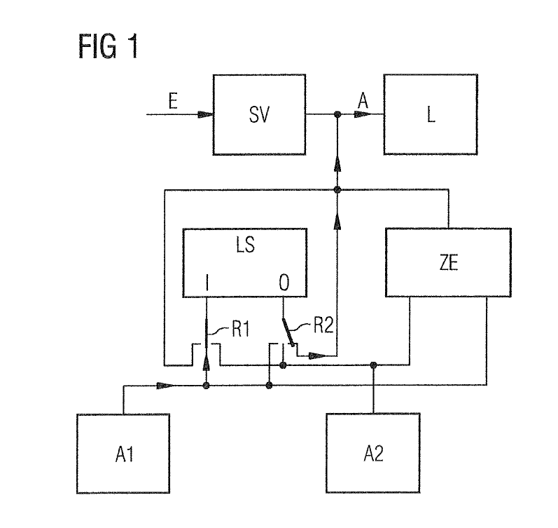

FIG. 1 shows a schematic diagram of a DC power supply unit in accordance with the invention. the DC power supply unit comprises a power supply SV, a charging circuit LS, two energy stores, in this case rechargeable batteries A1, A2, and a connection device ZE. The power supply SV makes the connection to the electrical utility supply and to the load L and has an input E for an input voltage. The load L can draw a DC output voltage or a load current via the output A of the DC power supply unit.

The charging circuit LS connects the two rechargeable batteries A1, A2 to the power supply SV and hence to the input E. With relays R1, R2 it is possible to connect either the first rechargeable battery A1 or the second rechargeable battery R2, or neither of the two rechargeable batteries to the charging circuit LS and hence to accordingly charge or not charge the rechargeable batteries. The connection device ZE connects either the first rechargeable battery A1 or the second rechargeable battery A2, or both rechargeable batteries A1, A2, or neither of the two rechargeable batteries to the output A and hence to the load L.

In the illustrated position of the relays R1, R2, the rechargeable battery A1 is connected to the input I of the charging circuit LS, and the output O is connected to the load L. The rechargeable battery A1 can thus be discharged fully via the load L in a first step. Should it be desired to discharge the rechargeable battery A2 instead, then relay R1 at the input I of the charging circuit LS would have to be switched to the right. During the discharge via the load, the capacity of the relevant rechargeable battery A1, A2 could likewise be determined from the measured current, the output voltage, or the time, albeit less accurately.

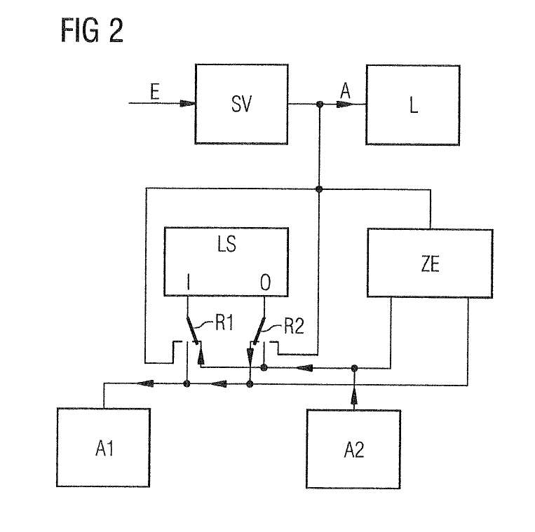

Once the first rechargeable battery A1 is fully discharged, the second step of the method in accordance with the invention begins, during which the first rechargeable battery A1 is charged from the second, fully charged rechargeable battery A2. In FIG. 2, in the position shown of the relays R1, R2, the two rechargeable batteries A1, A2 are accordingly connected together. The rechargeable battery A2 is discharged fully into the rechargeable battery A1 via the input I and output O of the charging circuit LS. The two relays R1, R2 would each be in the vertical position if, in the other situation, the empty second rechargeable battery A2 were meant to be charged from the fully charged first rechargeable battery A1.

The discharge current, voltage level and time for discharging the second rechargeable battery A2 into the first rechargeable battery A1 can be continuously measured using a current measuring device, voltage measuring device and a clock, none of which is shown here, and the capacity of the second rechargeable battery A2 can be calculated therefrom. If data from the manufacturer of the rechargeable battery A2 is available relating to determining the service life of the rechargeable battery A2, then the service life of the rechargeable battery A2 that still remains can be determined from the actual service life up to this point and from the measured values or the capacity determined according to the invention.

Once the rechargeable battery A2 is fully discharged into the rechargeable battery A1, the rechargeable battery A2 is recharged fully via the input E and the power supply SV. The charging current, voltage level and time for charging the second rechargeable battery A2 can be measured continuously using a current measuring device, voltage measuring device and a clock, none of which is shown here, and the capacity of the second rechargeable battery A2 can be calculated therefrom. If data from the manufacturer of the rechargeable battery A2 relating to determining the service life of the rechargeable battery A2 is available, then the service life still remaining can be determined from the actual service life up to this point and from the measured values or the capacity determined according to the invention.

If, in the inverse situation, the empty first rechargeable battery A1 is meant to be charged via the input E, then the relay R2 must be brought into the left position.

After the specified time period, such as after a month, the method in accordance with the invention is repeated, this time in order to determine the capacity of the first rechargeable battery A1. In this case, first rechargeable battery A1 and second rechargeable battery A2 swap roles. In the first step, the second rechargeable battery A2 is discharged via the load L, then, in the second step, the second rechargeable battery A2 is charged by the contents of the first rechargeable battery A1, and finally, in the third step, the first rechargeable battery A1 is recharged fully via the input E. The capacity of the first rechargeable battery A1 can be measured in the second step and/or in the third step.

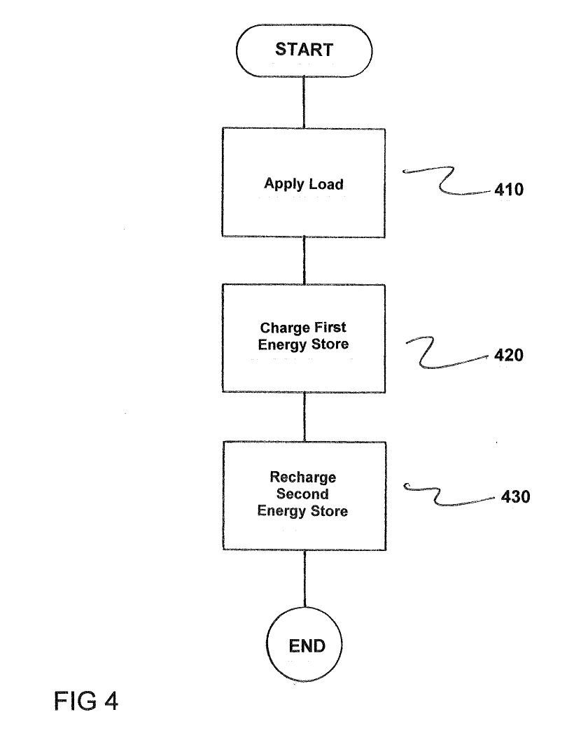

FIG. 4 is a flowchart of the method for determining the capacity of an energy store A1, A2 of a DC power supply unit for providing an uninterruptible supply of direct current to a load L, where the DC power supply unit comprises at least an input E for an input voltage, an output A for a DC output voltage, from which output a load L connected to said output can draw a load current, two similar energy stores A1, A2, which are charged by a charging current via the input E and which, in backup mode, provide a replacement DC output voltage, and where a capacity of each of the two energy stores A1, A2 is dimensioned such that one energy store alone can provide the backup mode.

The method comprises applying the load L to the output to fully discharge a charged first energy store A1 at specified time intervals via the load L applied to the output A, as indicated in step 410.

Next, charging the first energy store A1 from the fully charged second energy store A2, as indicated in step 420.

Next, the second energy store A2 is fully recharged via the input E, as indicated in step 430.

In accordance with the method of the invention, either (i) a capacity taken from the second energy store A2 is measured during the charging of the first energy store (A1) and/or (ii) the capacity charged into the second energy store A2 is measured during the full recharging of the second energy store

A2.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-11. (canceled)

12. A method for determining a capacity of an energy store of a DC power supply unit for providing an uninterruptible supply of direct current to a load, the DC power supply unit comprising at least an input for an input voltage, an output for a DC output voltage, from which output a load connected to said output can draw a load current, two similar energy stores, which are charged by a charging current via the input and which, in backup mode, provide a replacement DC output voltage, a capacity of each of the two energy stores being dimensioned such that one energy store alone can provide the backup mode, the method comprising:
applying the load to the output to fully discharge a charged first energy store at specified time intervals via the load applied to the output;
charging the first energy store from the fully charged second energy store; and
recharging the second energy store fully via the input;
wherein during at least one of (i) a capacity taken from the second energy store is measured during said charging the first energy store and (ii) the capacity charged into the second energy store is measured during said recharging the second energy store fully.

13. The method as claimed in claim 12, wherein the first energy store is charged from the fully charged second energy store under constant current during said charging the first energy store.

14. The method as claimed in claim 12, wherein the second energy store is recharged fully by constant current via the input.

15. The method as claimed in claim 13, wherein the second energy store is recharged fully by constant current via the input.

16. The method as claimed in claim 12, wherein the replacement DC output voltage of the second energy store is also measured in addition to the capacity of the energy store.

17. The method as claimed in claim 13, wherein the replacement DC output voltage of the second energy store is also measured in addition to the capacity of the energy store.

18. The method as claimed in claim 14, wherein the replacement DC output voltage of the second energy store is also measured in addition to the capacity of the energy store.

19. The method as claimed in claim 12, wherein a device is provided to measure an absolute service life of the energy stores.

20. The method as claimed in claim 12, wherein an expected service life of the energy store is determined from measured capacity, measured replacement DC output voltage and measured absolute service life when measuring the capacity of the energy store, and based on manufacturer data about the energy store.

21. The method as claimed in claim 12, wherein the method in according with the invention is performed at specified time intervals alternately, in one case starting with the first energy store, and in another case starting with the second energy store.

22. The method as claimed in claim 12, wherein a specified time interval is selectable.

23. The method as claimed in claim 22, wherein the specified time intervals equals one month.

24. A non-transitory computer program product encoded with a computer program which, when loaded directly into a memory of a processor of the DC power supply unit and which, when executed by the processor, causes creation of a replacement DC output voltage, the computer program comprising:
program code for applying a load to an output to fully discharge a charged first energy store at specified time intervals via the load applied to the output;
program code for charging the first energy store from the fully charged second energy store; and
program code for recharging the second energy store fully via the input;
wherein during at least one of (i) a capacity taken from the second energy store is measured during said charging the first energy store and (ii) the capacity charged into the second energy store is measured during said recharging the second energy store fully.

25. A DC power supply unit for an uninterruptible supply of direct current to a load, the DC power supply unit comprising:
an input for an input voltage;
an output for a DC output voltage, a load current being drawn by a load connected to said output;
two similar energy stores which are each chargeable by a charging current via the input, and which during backup mode provide a replacement DC output voltage;
wherein a capacity of each of the two energy stores is dimensioned such that one energy store alone provides the backup mode;
wherein the first energy store and the second energy store include a switchable connection comprising one of (i) relays and (ii) semiconductor switches, via which the first energy store is chargeable from the second energy store, and via the second energy store is chargeable from the first energy store; and
wherein each energy store of the two energy stores is provided with a device for measuring the capacity.

26. The DC power supply unit as claimed in claim 25, further comprising:
a closed-loop control unit which regulates the charging current of the energy stores to a constant value.
